(19) United States
(12) Patent Application Publication
(10) Pub. No.: US 2024/0426881 A1
(43) Pub. Date: Dec. 26, 2024

(54) SYSTEMS AND METHODS FOR USING A POWER DETECTOR IN A TRANSMISSION PATH

(71) Applicant: Qorvo US, Inc., Greensboro, NC (US)

(72) Inventors: Jorgen Bojer, Vadum (DK); Søren Deleuran Laursen, Vestbjerg (DK)

(21) Appl. No.: 18/749,770

(22) Filed: Jun. 21, 2024

Related U.S. Application Data
(60) Provisional application No. 63/509,844, filed on Jun. 23, 2023.
(60) Provisional application No. 63/509,851, filed on Jun. 23, 2023.
(60) Provisional application No. 63/509,858, filed on Jun. 23, 2023.
(60) Provisional application No. 63/509,865, filed on Jun. 23, 2023.
(60) Provisional application No. 63/509,872, filed on Jun. 23, 2023.
(60) Provisional application No. 63/509,879, filed on Jun. 23, 2023.

(51) Int. Cl. G01R 21/14; G01R 19/10; H04B 17/13

(52) U.S. Cl. CPC G01R 21/14; G01R 19/10; H04B 17/13

(57) ABSTRACT

A power detector in a transmission path is disclosed. In one aspect, a power detector may be coupled to an output node for a transmission path. The power detector may be used to throttle a power amplifier to protect the power amplifier or other elements (e.g., an acoustic filter) from overpower conditions. The power detector may separately detect both a forward power signal as well as a reverse or reflected power signal (e.g., from an antenna). In a particularly contemplated aspect, the reverse detector only generates an output when the reverse signal exceeds a programmable threshold. This threshold allows the reverse signal to be ignored in low power conditions and helps avoid premature throttling.

### PRIORITY APPLICATIONS

This application claims the benefit of U.S. Provisional Patent Application Ser. No. 63/509,844, filed on Jun. 23, 2023, the disclosure of which is hereby incorporated herein by reference in its entirety.

This application claims the benefit of U.S. Provisional Patent Application Ser. No. 63/509,851, filed on Jun. 23, 2023, the disclosure of which is hereby incorporated herein by reference in its entirety.

This application claims the benefit of U.S. Provisional Patent Application Ser. No. 63/509,858, filed on Jun. 23, 2023, the disclosure of which is hereby incorporated herein by reference in its entirety.

This application claims the benefit of U.S. Provisional Patent Application Ser. No. 63/509,865, filed on Jun. 23, 2023, the disclosure of which is hereby incorporated herein by reference in its entirety.

This application claims the benefit of U.S. Provisional Patent Application Ser. No. 63/509,872, filed on Jun. 23, 2023, the disclosure of which is hereby incorporated herein by reference in its entirety.

This application claims the benefit of U.S. Provisional Patent Application Ser. No. 63/509,879, filed on Jun. 23, 2023, the disclosure of which is hereby incorporated herein by reference in its entirety.

### BACKGROUND

### I. Field of the Disclosure

The technology of the disclosure relates generally to a power detector that may be used with a wireless transmitter.

### II. Background

Communication devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to make the devices more efficient by extending the time between recharging and concurrently reducing the size of internal components. These pressures provide room for innovation, particularly in the transmission portions of the devices.

### SUMMARY

Aspects disclosed in the detailed description include systems and methods for using a power detector in a transmission path. In particular, aspects of the present disclosure provide a power detector that may be coupled to an output node for a transmission path. The power detector may be used to throttle a power amplifier to protect the power amplifier or other elements (e.g., an acoustic filter) from overpower conditions. The power detector may separately detect both a forward power signal as well as a reverse or reflected power signal (e.g., from an antenna). In a particularly contemplated aspect, the reverse detector only generates an output when the reverse power signal exceeds a programmable threshold. This threshold allows the reverse power signal to be ignored in low-power conditions and helps avoid premature throttling.

The forward power detector, in an exemplary aspect, has a combination of a primary detector and a boost detector. The primary detector operates at higher signal levels, and the boost detector detects at lower signal levels. This combination of detectors provides a high dynamic range of detection with fast rise and fall times while preserving high accuracy.

The high accuracy of the power detector allows the use of the power detector in self-calibration circuits, which may assist in device integration and testing.

In this regard, in one aspect, a power detector is disclosed. The power detector includes a forward power detector circuit configured to receive a forward signal from a coupler associated with a transmission path conductor and a reverse power detector circuit configured to receive a reverse signal from the coupler associated with the transmission path conductor, wherein the reverse signal is based on a signal reflected from an antenna. The power detector also includes a summing node configured to receive a first current from the forward power detector circuit, receive a second current from the reverse power detector circuit, and sum the first current and the second current into a combined power detected signal.

In this regard, in one aspect, a mobile communication device is disclosed. The mobile communication device includes a transmission chain comprising a baseband processor (BBP), a power amplifier coupled to the BBP, and a power detector coupled to an output of the power amplifier. The power detector comprising a forward power detector circuit configured to receive a forward signal from a coupler associated with a transmission path conductor, a reverse power detector circuit configured to receive a reverse signal from the coupler associated with the transmission path conductor, wherein the reverse signal is based on a signal reflected from an antenna and a summing node. The summing node is configured to receive a first current from the forward power detector circuit, receive a second current from the reverse power detector circuit, and sum the first current and the second current into a combined power-detected signal.

In this regard, in one aspect, a method of calibrating a mobile communication device is disclosed. The method includes detecting a forward signal downstream of a power amplifier, detecting a reverse signal reflected from an antenna downstream of the power amplifier, and providing the detected signal to an autocalibration circuit.

### BRIEF DESCRIPTION OF THE DRAWINGS

FIG. 1A is a block diagram of a portion of a transmission chain illustrating forward and reverse signals;

FIG. 1B is a block diagram of a transmission chain with a power detector and an overpower throttle circuit that may be used to protect the power amplifier;

FIG. 2 is a circuit diagram of a power detector having forward and reverse detection circuits according to aspects of the present disclosure;

FIG. 3 is a graph illustrating a programmable threshold for the reverse detection circuit and its contribution to a detection signal;

FIG. 4 is a circuit diagram illustrating a current limiter for the reverse power detector;

FIG. 5 is a circuit diagram illustrating a programmable resistor used in a bias circuit for the reverse power detector and a programmable current mirror operating on the reverse power detected signal;

FIG. 6 is a circuit diagram highlighting the shared bias circuit with a programmable resistor in the bias circuit as well as features to assist in keeping operation consistent through process, voltage, and temperature variations;

FIG. 7 is a circuit diagram of a shunt and series network to provide a programmable resistor;

FIG. 8 is a circuit diagram illustrating an exemplary circuit to provide a direct current (DC) level shift for tracking a reference voltage;

FIG. 9 is a circuit diagram of a DC current compensation circuit used to offset DC current introduced from size mismatches in a current mirror;

FIG. 10 is a circuit diagram of an alternate power detector where the bias circuit for the reverse power detector is below a diode stack instead of above, as illustrated in FIG. 2;

FIG. 11 is a circuit diagram of a circuit to pull current from a current mirror to increase an abruptness of current mirror turning on;

FIG. 12A is a block diagram of a power detector used with an autocalibration circuit;

FIG. 12B is a flowchart for using the power detector and autocalibration circuit of the present disclosure; and

FIG. 13 is a block diagram of a communication device, which may include the power detector according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include systems and methods for using a power detector in a transmission path. In particular, aspects of the present disclosure provide a power detector that may be coupled to an output node for a transmission path. The power detector may be used to throttle a power amplifier to protect the power amplifier or other elements (e.g., an acoustic filter) from overpower conditions. The power detector may separately detect both a forward power signal as well as a reverse or reflected power signal (e.g., from an antenna). In a particularly contemplated aspect, the reverse detector only generates an output when the reverse signal exceeds a programmable threshold. This threshold allows the reverse signal to be ignored in low-power conditions and helps avoid premature throttling.

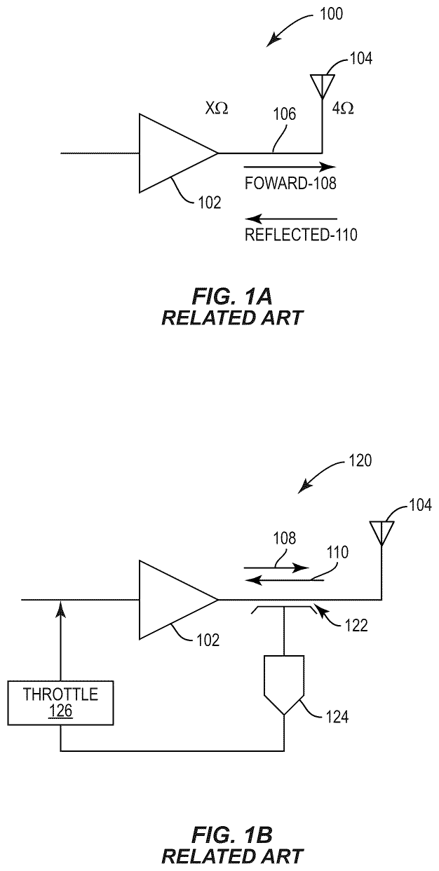

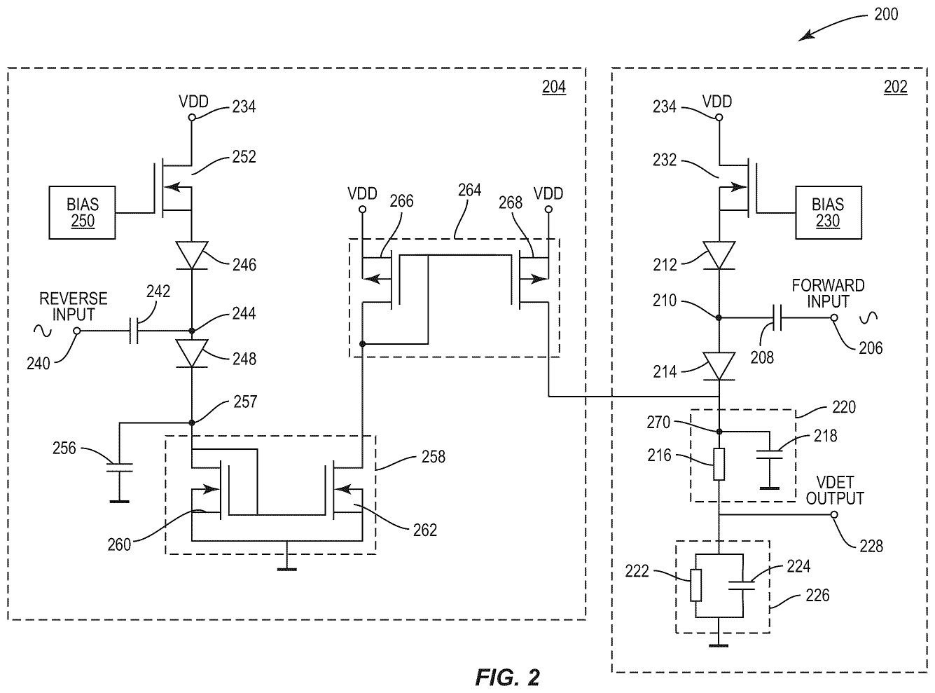

Before addressing aspects of the present disclosure, a brief overview of a transmission chain and power detectors used therewith is provided with reference to FIGS. 1A & 1B. A discussion of aspects of the present disclosure begins below with reference to FIG. 2.

In this regard, FIG. 1A illustrates a part of a transmission chain 100 having a power amplifier 102 and an antenna 104 connected to one another by a conductor 106. Signals to be transmitted pass through the power amplifier 102 and are amplified. The power amplifier 102 may have an output impedance X (as in X ohms, typically fifty ohms). By design, the conductor 106 will have the same impedance as the output impedance (i.e., X ohms). However, the antenna 104 may have a different impedance Y (as in Y ohms, e.g., 277 ohms corresponding to the general resistance of air for a microwave signal). Note that the resistance of air is frequency dependent, and thus, the antenna 104 may have its impedance selected for a likely operating frequency, but changes in signal frequency may change the impedance mismatch. While there may be an impedance-matching circuit (not shown), there are many instances where the impedance mismatch between the conductor 106 and the antenna 104 results in a reflected signal. Thus, the conductor 106 may have a forward signal 108 and a reflected or reverse signal 110 thereon.

Unchecked, the signals on the conductor 106 may constructively sum and cause excessive current drain through the power amplifier 102, which may cause damage to one or more elements in the transmission chain 100. This sort of damage is not necessarily limited to the power amplifier 102 but could also include acoustic filters (not shown) or the like.

Accordingly, it is not uncommon to have some form of overpower protection circuit. The overpower condition may be estimated by measuring voltage, current, the combination, or the like. Thus, FIG. 1B illustrates a part of a transmission chain 120 that adds a coupler 122 and a power detector 124 that operate with a throttle circuit 126 to throttle the power amplifier 102. In some aspects, this throttle circuit 126 may adjust a bias signal provided to the power amplifier 102, may be a clamp (not shown), may adjust a bias for a prior stage in the transmission chain 120, or the like. While not shown explicitly, it is also possible that the power amplifier 102 is a variable gain amplifier (VGA), and the throttle circuit 126 may be connected directly to the power amplifier 102 (instead of upstream as illustrated), or the throttle circuit 126 may be integrated into the power amplifier 102. Relevantly (and regardless of position), the throttle circuit 126 effectively limits the size of the forward signal 108. Limiting the size of the forward signal 108 necessarily limits the size of the reverse signal 110 (i.e., the reverse signal 110 is never greater than the forward signal 108 and is usually some predictable percentage of the forward signal 108, depending on the mismatch of impedances).

While knowing the total sum of the forward signal 108 and the reverse signal 110 is useful, there may be occasions when it is useful to know the size of the signals separately. A properly designed coupler will allow the signals to be extracted and measured independently of one another. Likewise, below a certain value, the reverse signal is meaningless from an efficiency or overpower condition perspective and can be ignored.

Thus, exemplary aspects of the present disclosure contemplate a power detector 200, illustrated in FIG. 2, with a forward power detector 202 and a reverse threshold power detector 204. The forward power detector 202 has an input node 206 that passes signals through a blocking capacitor 208. The signal at node 210 is diode rectified by diodes 212, 214 to create a direct current (DC) signal proportional to the alternating current (AC) signal at the input node 206. A resistor 216 and a capacitor 218 provide a first filter 220. A shunt filter 226 is formed from a second resistor 222, and a second capacitor 224. An output node 228 is positioned between the first filter 220 and the shunt filter 226. A bias circuit 230 and a transistor 232 may be used with ground or supply voltage 234 (Vdd) to bias the diodes 212, 214.

Similarly, the reverse threshold power detector 204 may have an input node 240 that passes signals through a blocking capacitor 242. The signal at node 244 is diode rectified by diodes 246, 248 to create a DC signal proportional to the alternating current AC signal at the input node 240. A bias circuit 250 and a transistor 252 may be used with supply voltage 234 to bias the diodes 246, 248. The transistor 252 may be a programmable voltage follower and may be used to set the threshold, as explained below. A capacitor 256 may couple a node 257 to ground. The node 257 is also coupled to ground through a first current mirror 258 formed from a diode-connected transistor 260 and a second transistor 262. By connecting the transistor 260 as a diode-connected transistor, the first current mirror 258 does not turn on until a predefined threshold is surpassed at node 257. That is, the diode 246 and the diode 248 make an effective diode stack with a defined voltage drop thereacross. Only when the voltage at node 257 (after the voltage drop of the diode stack) exceeds the voltage drop of the transistor 260 will the first current mirror 258 turn on. Thus, the supply voltage 234, minus the programmable transistor 252 drop, minus the drops across the diodes 246, 248, plus the voltage from the reverse signal will turn on the first current mirror 258 when the voltage from the reverse signal exceeds the activation of the transistor 260. By changing the voltage drop across the transistor 252, the voltage of the node 257 may be controlled such that the reverse signal pushes the node 257 above the activation of the transistor 260 only when the reverse signal is larger than the predefined threshold. Thus, at low reverse signal levels, reverse threshold power detector 204 will not generate an output signal.

The first current mirror 258 is coupled to a second current mirror 264 formed from transistors 266, 268. The second current mirror 264 acts as a programmable current amplifier, and the current is added to the current at the node 270 between the diode 214 and the resistor 216. This coupling allows the reverse signal to be summed with the forward signal at the output node 228 (currents being easier to sum than voltages). As discussed above, below a certain threshold, the reverse signal is not summed because the first current mirror 258 is not turned on yet.

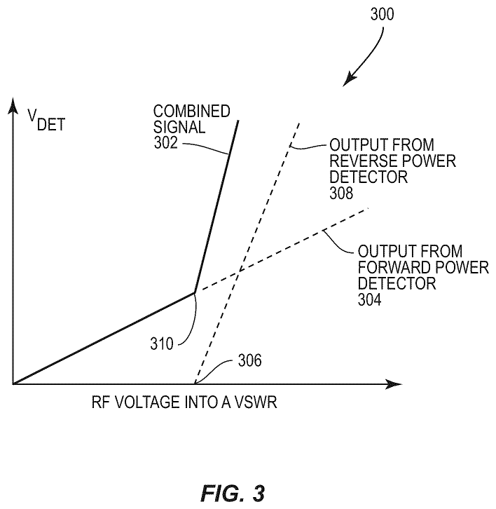

This threshold function is better illustrated in graph 300 in FIG. 3, where initially, the output 302 at output node 228 is just the forward signal (line 304), but at some threshold 306, the reverse signal (line 308) turns on and is then summed with the forward signal, resulting in the corner 310.

Note that it is possible to turn off the forward power detector 202 and only use the reverse threshold power detector 204 (e.g., in 4G or 5G type systems where there is no control of the forward power contemplated). The use of both the forward and reverse power detectors 202, 204 is well suited for use in a 2G system that allows for regulation of the forward power.

Historically, AC signal detectors rely on finding a “sweet spot” of the detection device by setting a proper DC operating point. A low-frequency output signal will represent the instantaneous amplitude of the AC input signal. The AC operation will have a limited dynamic range with the input signal amplitude. This range may be small relative to a system (e.g., 2G, 4G, or 5G) where larger power ranges can be expected. While one solution is to use a logarithmic detector, such an approach has limitations.

Aspects of the present disclosure contemplate adding a boost circuit to the forward detector 202. This addition allows the forward detector to operate over a normal range (e.g., −20 to −5 dBm from the input node 206) and not significantly detect signals below this range. The boost circuit is also coupled to the input node 206 and allows the detection of signals at a low signal range (e.g., −35 to −20 dBm) but does not detect signals in the range of the primary forward detector. Signals from the two detectors should be able to be combined without significantly increasing signal detection tolerances (e.g., the current from the reverse threshold power detector 204 is unidirectional to assist in this combination).

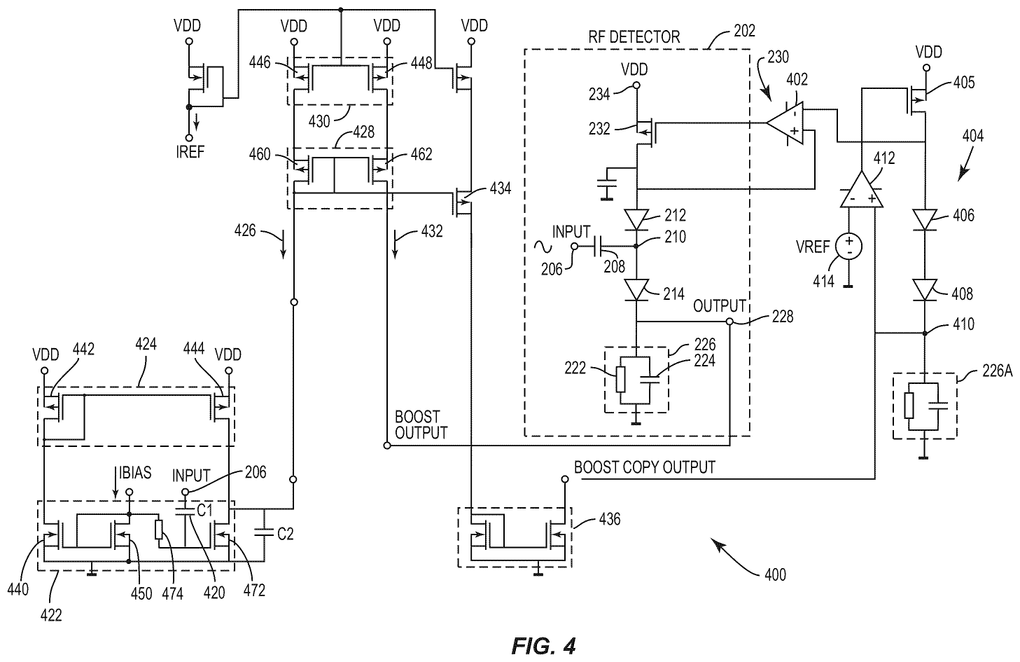

In this regard, FIG. 4 illustrates a boost circuit 400 added to the forward detector 202. It should be appreciated that the reverse threshold power detector 204 and other portions of the power detector 200 readily combine with the boost circuit 400 but are omitted (along with the resistor 216 and capacitor 218) for clarity in the discussion of the boost circuit 400. Further, the bias circuit 230 is an op-amp 402 coupled to a diode reference circuit 404 formed from transistor 405, diodes 406, 408, and a matching filter 226A and having a diode reference node 410. The bias circuit 230 includes a bias control circuit 412 that is an op-amp with one input node connected to the diode reference node 410 and one input node connected to a DC reference voltage 414.

The boost circuit 400 is coupled to the input node 206 through a blocking capacitor 420. Signals from the input node 206 are mirrored through first current mirror 422 and second current mirror 424 to pull current 426 in a third current mirror 428. A fourth current mirror 430 acts as a current limiter. The third current mirror 428 generates a boost output signal 432, which is summed with the signal from the forward detector 202 at the output node 228. Additionally, a copied signal is generated in the transistor 434 and mirrored through current mirror 436 to be added to the diode reference node 410. Variations on these current mirrors and the rationales about why such variations may be appropriate are discussed below.

Supplying the copied signal to the diode reference node 410 ensures that the bias current of the main detector will stay significantly unchanged when combining at the output node 228, thereby ensuring that the detection tolerance of the total combined detector output signals stays low or significantly unchanged from individual detector tolerances.

As alluded to above, there may be a desire to cut off the signal from the boost circuit 400 above certain thresholds. The current limiter current mirror 430 is one approach and has the benefit of avoiding reliance on feedback circuitry. More specifically, the transistors 440, 442, and 444 act as DC cancellation (as better explained below), while the transistors 446 and 448 operate with the current limiter current mirror 430. The current limiter current mirror 430 could use degenerative resistors, but the degenerative transistor devices of the third current mirror 428 are also useful. That is, the transistors 460, 462 are coupled between the source of transistors 446, 448 and any ground node. The degeneration transistors 460, 462 are biased as current sources but operate in two modes. At low signal levels, the transistors 460, 462 operate in the triode region as a resistive load, but at higher signal levels, the transistors 460, 462 will operate in saturated mode.

Additionally, the boost circuit 400 may be considered a FET device coupled as a transconductance stage, with the AC input signal capacitively coupled from the input node 206 through the capacitor 420 to a gate input and drain output of a transistor 450 in the first current mirror 422. The transistor 450 acts as a detector by detecting changes in DC sink current through the transistor 450.

As noted above, one of the things the power detector 200 may be used for is to control both target forward power levels and, based on the instantaneous reflected power level, reduce the forward power below the set target power level. Combining the forward and reverse power detectors 202 and 204 into a single die with a single output may allow for a reduction in pin counts, even if the power control circuitry is still in another die.

As alluded to above, it is possible to tap the reverse threshold power detector 204 at a reverse output node prior to node 270 (i.e., between the transistor 268 and the node 270). Based on this, it is possible for a control circuit to subtract the reverse signal from the forward signal if desired. Not further, it is possible to omit the second current mirror 264 and couple the first current mirror 258 directly to the node 270.

While it is implicit in the discussion above, it should be appreciated that the resistor 216 provides the ability to generate the output at the output node 228. The resistor 216 is coupled, through the filter 226, to ground and to the combining node 270. The resistor 216 converts the summed current to a voltage at the output node 228. Note further, the current from the reverse threshold power detector 204 is unidirectional while the current from the forward power detector 202 may be non-unidirectional. If both currents were non-unidirectional, then the current of one could potentially change the current of the other in an undesirable manner. While the resistor 216 is elegant and size appropriate, in an alternate aspect, the resistor 216 may be replaced with another current mirror to provide the same functions, albeit at a space penalty.

It should further be appreciated that in some circuits, it may be desirable to remove or at least reduce DC offsets that come from biasing devices such as transistors or diodes. As seen above, the present disclosure relies heavily on transistors, diodes, and diode-connected transistors, and the ability to change the DC bias current contribution may allow for increased dynamic range and/or to change a pedestal level to near zero. Still further, removal of DC bias may allow the summed signals at the node 270 to be only from AC contributions. Furthermore, since bias may drift over temperature, the removal of such DC bias helps provide more stable operation over wider temperature ranges.

The DC cancelation of the present disclosure introduced above contemplates the first current mirror 422, where a first transistor 472 is coupled through resistor 474 to an input of the first current mirror 422 and acts as the detection device. In an exemplary aspect, the transistors 440, 450 of the first current mirror 422 are NFETs. An output of the first current mirror 422 is coupled to the second current mirror 424, which is based on PFETs (i.e., transistors 442, 444 are PFETs). An output of the second current mirror 424 is coupled to an output of the transistor 472 (i.e., the drain of the transistor 472), thereby subtracting out the DC bias contribution. And, as noted above, the drain of the transistor 472 is also coupled (through the current limiter) to the output node 228. In exemplary aspects, the first and second current mirrors 422, 424 are scaled so the output current of the second current mirror 424 is nominally equal to the output current of the transistor 472. In another aspect, the first and second current mirrors 422, 424 are scaled so the output of the second current mirror 424 is smaller than the output current of the transistor 472 so that the difference current is always a little positive over process mismatch.

A bias current (IBIAS) is mirrored in the first current mirror 422 from a transistor 450 to a transistor 472. The current in the transistor 472 pulls current through the transistor 444. This mirroring reduces current 426 towards zero current when no AC signal is present on input node 206 and deviates the idle DC current of the transistor 472 from the current 426 to the transistor 444.

While not shown, it should be appreciated that many of the transistors described herein could be implemented with cascode configurations.

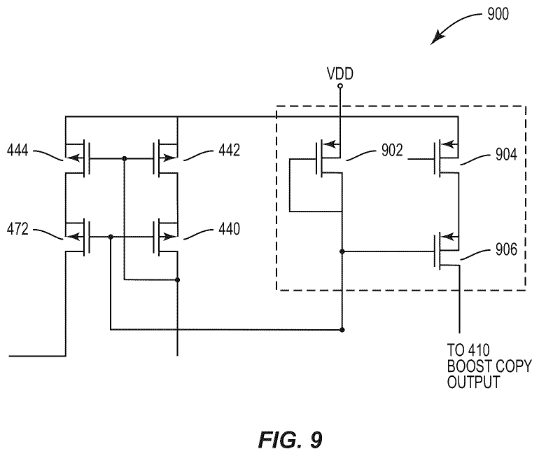

Returning to FIG. 4, it should be appreciated that the current going through the transistor 444 subtracts from the current going into transistor 472, so there is minimal DC current in current 426. In practice, there are mismatches between transistors 444 and 442 as well as between transistors 472 and 440. When this mismatch is weighted the “wrong” way, then transistor 472 may sink too little current, and the current 426 is off until the AC signal exceeds a threshold. So below that threshold, there is no detection. This lack of detection (in this context) is undesirable. Accordingly, the transistor 444 is designed to be smaller than the transistor 442. This ratio means that there is more DC signal in current 426, but the current 426 will not turn off (i.e., the threshold is zero). To compensate for this DC component, a compensation is provided so that there is no disturbance on the main detector (i.e., output node 228). The compensation circuit 900 is illustrated in FIG. 9.

In this regard, the compensation circuit 900 includes transistors 902 and 904, which are effectively mirrored in with the transistors 442/444. An additional transistor 906 is positioned between the transistor 904 and the node 410.

Note also that an additional PMOS device with source/gate connected similar to transistors 442 or 444 and having its drain connected to the node 410 may provide additional benefits beyond the current mirror 436 and/or current mirror 436 may be omitted.

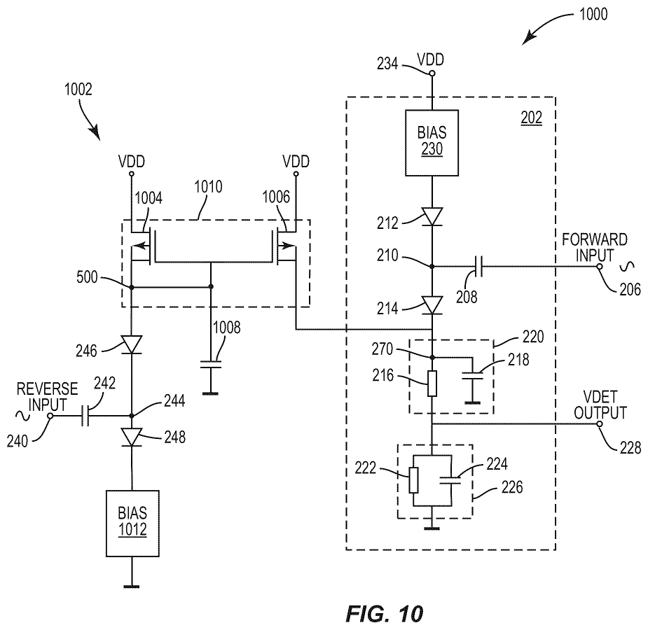

As another possible variation, the placement of the bias circuit may be changed, as better illustrated in FIG. 10 by power detector 1000. The power detector 1000 includes a forward power detector 202, as previously described, and the reverse power detector 1002 still receives a reverse power signal at the input node 240 to be rectified by diodes 246, 248. However, a current mirror 1010 is formed by transistors 1004 and 1006 between the diode 246 and Vdd. A capacitor 1008 is also used to couple the current mirror 1010 to ground. The current from current mirror 1010 is provided to the node 270 to be summed with the forward power signal. A bias circuit 1012 couples the diode 248 to ground. Still other topologies are possible without departing from the present disclosure.

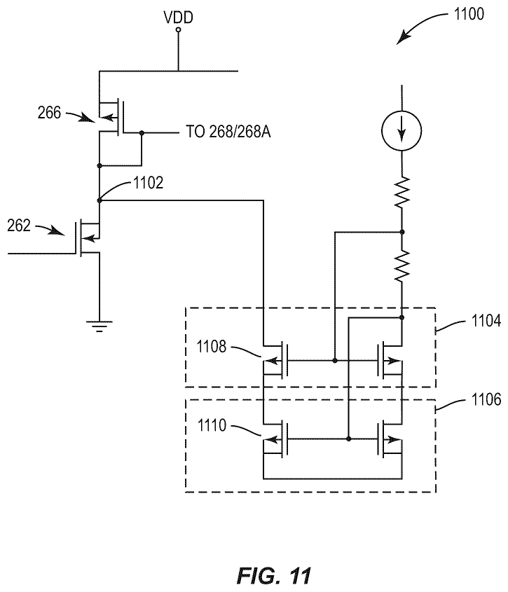

As another variation, to increase the abruptness with which the transistor 266 starts conducting current in the reverse threshold power detector 204, a current stealing circuit 1100 may be provided, as illustrated in FIG. 11. Specifically, the current stealing circuit 1100 couples to a node 1102 between the transistors 262 and 266 and includes a first current mirror 1104 and a second current mirror 1106. The current mirrors 1104, 1106 are effectively a cascoded current mirror given the same functionality as 258, where the transistors 1110 are equivalent to the transistor 260. In effect, the transistors 1108, 1110 add a second threshold to the reverse threshold power detector 204.

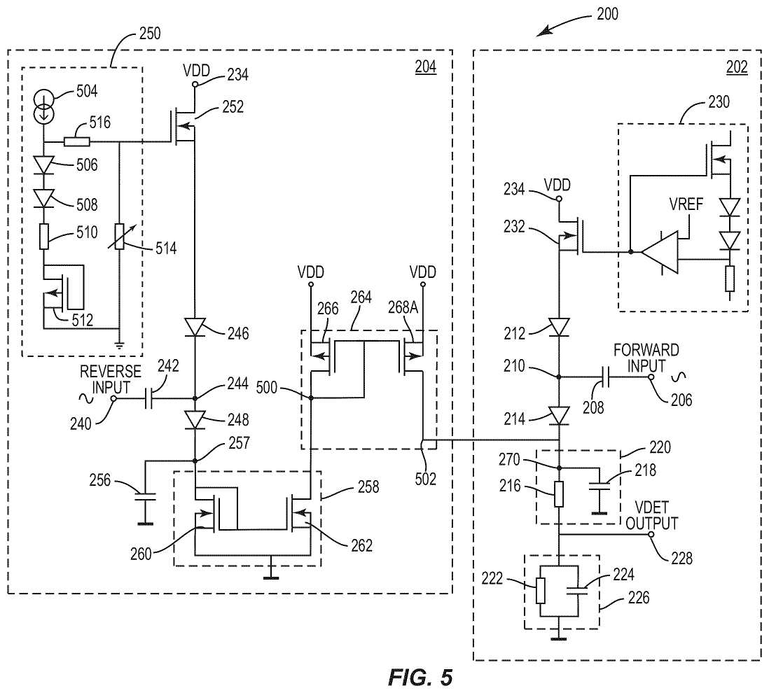

The power detector 200 relies on the ability to have programmable thresholds. This programmable threshold is possible by having a programmable voltage level output for biasing detection devices (e.g., the diodes 212, 214, or 246, 248). Further control may be achieved by controlling a ratio of the devices in the second current mirror 264. FIG. 5 provides additional details about the bias circuit 250 and the second current mirror 264.

The second current mirror 264 may be referenced to ground (Vdd) and includes an input node 500 and an output node 502. The first transistor 266 acts as an input device and may have one device scaling (W/L). The second transistor 268A has a second device scaling and circuitry to scale the second device scaling by a logic level input signal so that the scaling is programmable. In essence, the logical level input signal adds additional area (W/L) to the second transistor 268A to change the current flow therethrough. This scaling can also be done with a binary weighted array of transistors in place of the second transistor 268A that are logically controlled and enabled or disabled by switching in or out the connection to their respective gates of the array binary weighted transistors used in place of transistor 268A or otherwise connected to the respective gates to Vdd for transistors of the binary array that are intended to be disabled.

The bias circuit 230 is discussed above, and changes to the reference voltage allow changes to the bias provided to the transistor 232.

The bias circuit 250 has a programmable voltage level output for biasing the diodes 246, 248, and the transistor 260, thereby setting the level for when the first current mirror 258 starts conducting current. The bias circuit 250 may be analog or digitally controlled. In an exemplary aspect, the bias circuit 250 may include a current source 504 coupled to diodes 506, 508, a resistor 510, and a diode-connected transistor 512. A programmable resistor 514 may be coupled to the transistor 252 and a feedback resistor 516. Additional details about the programmable resistor 514 are set forth below.

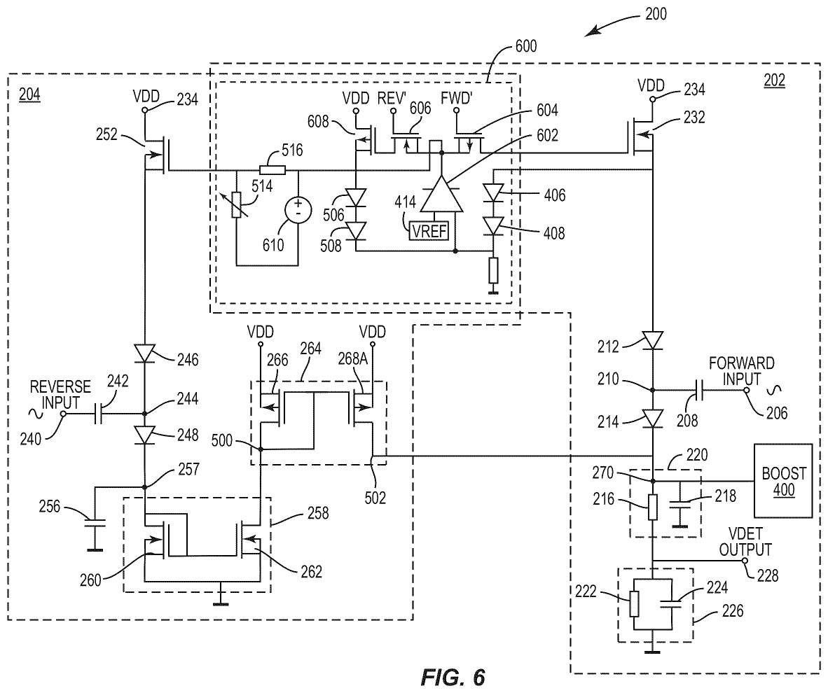

It should also be appreciated that the bias circuits 230 and 250 may be combined into a single bias circuit 600, illustrated in FIG. 6, where the reference voltage 414 still provides an input for an op-amp 602, but the other input for the op-amp 602 comes from both the diodes 406, 408 and the diodes 506, 508. The output of the op-amp 602 is coupled to a forward transistor 604 and a reverse transistor 606. The forward transistor 604 couples to the gate of the transistor 232. The reverse transistor 606 couples to another transistor 608, which drives the diodes 506, 508. The output of the op-amp 602 is also coupled to the transistor 252 through the resistor 516. One terminal of the resistor 516 is coupled to the programmable resistor 514, and the other terminal of the resistor 516 is coupled to a voltage source 610 (which is analogous to the current source arrangement described in FIG. 5). Thus, the resistor divider of the resistors 514, 516 are in essence the DAC with a top rail connected to resistor 516 and the bottom rail being the negative terminal of the voltage source 610.

Digital programmable resistors have a limited number of bits with which to set the resistance. A typical number of bits might be three. A designer may have to make a compromise between minimum programmed resistance and maximum programmed resistance. The choice is usually between a series resistor network and a shunt conductance network. A series resistor network cannot have infinite resistance unless one bit is sacrificed to make such a designation, and a shunt conductance network cannot have zero impedance unless one bit is sacrificed to make such designation.

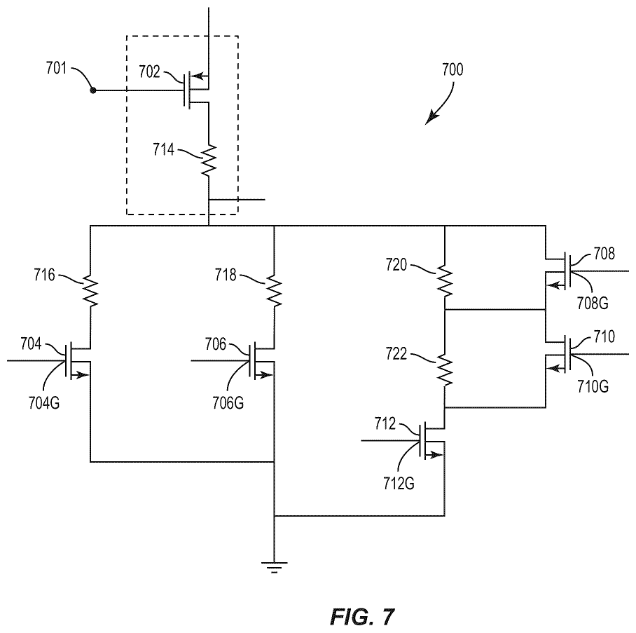

Aspects of the present disclosure offer an alternative programmable resistor 700 (sometimes referred to as a resistive programmable divider network) that allows low and high impedances without sacrificing bits. This programmable resistor 700 may be used for programmable resistor 514. Aspects of the present disclosure combine a shunt conductance network with a series resistance network, as illustrated in FIG. 7. An input node 701 connects to a gate of a transistor 702. A resistor 714 (equivalent to resistor 516) couples to the programmable resistor. A DAC (not shown) may control switches formed from transistors 704, 706, 708, 710, and 712 having gates 704G, 706G, 708G, 710G, and 712G. By turning the switches on and off, resistors 716, 718, 720, and 722 may be selectively coupled to create the desired net resistance. The topology reuses the least significant bits (LSBs) for each range or mode of operation. The most significant bit (MSB) controls the mode/range of operation. The bits for controlling the shunt resistors 716, 718 are reused for controlling series transistors 710, 708. Thus, the LSB couples to the gates 704G and 710G, and the MSB couples to gate 712G. Assuming an 3-bit DAC, the (eight) states may be determined as set forth in the following table, although other networks and bit arrangements may be used without departing from the disclosure.

TABLE 1

| | |
|---|---|
| 0 | All resistors off or an open circuit |
| 1 | Resistor 716 on |
| 2 | Resistor 718 on |
| 3 | Resistors 716/718 on |
| 4 | Resistor 720 and 722 on in series |
| 5 | Resistors 720/716 on |
| 6 | Resistors 722/718 on |
| 7 | 0 ohms = short circuit |

In the event that it is not explicit above, it should be appreciated that power detectors such as power detector 200 may be susceptible to non-linear, or at least variable, behavior as a function of process variations, temperature, and/or voltage variations (sometimes generically described or grouped as PVT variations). Such non-linearities or variable behavior may be undesirable or cause inaccurate readings by the power detector 200. In the power detector 200, where there is a voltage source, an input resistor, a current mirror, and an output resistor (intended to provide the voltage drop for voltage source 610), the input current is affected by a voltage drop (e.g., Vgs) on the input to the current mirror, which also affects the output current and thereby the voltage drop over the output resistor will vary with the Vgs drop.

Aspects of the present disclosure provide a solution for this variability by removing the dependency of the input drop (e.g., Vgs). This removal is done through addition, namely adding another Vgs drop to the output voltage shift so both the input and the output have the Vgs drop included. While Vgs is used for the purposes of illustration given a simple current mirror, the broader concept of adding a complementary drop to the output relative to the input may provide the same sort of PVT independence.

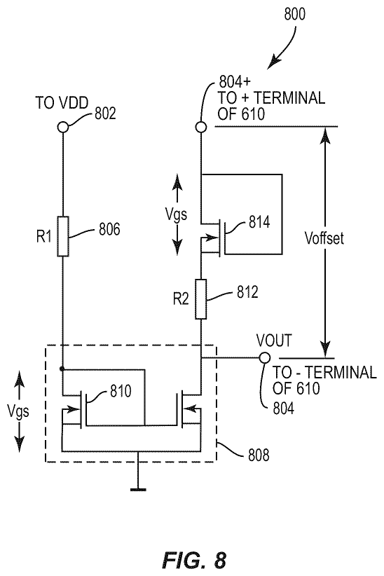

This arrangement is illustrated by circuit 800, corresponding to the voltage source 610, in FIG. 8, having an input node 802 and an node 804− (the negative terminal of the voltage source 610) while 804+ is the positive terminal of the voltage source 610). The input node 802 is coupled to Vdd and an input resistor 806, which, in turn, is coupled to a current mirror 808, which has a first voltage drop Vgs across a transistor 810. The current mirror is coupled to an output resistor 812. To facilitate having the same Vgs for both resistors 806, 812, a transistor 814 is added in series with the output resistor 812, thereby generating a desired offset voltage.

It may also be desirable to have a voltage output that can be programmed to different voltage levels and track absolute temperature variations. A DAC may be used to provide the different voltage levels, but the challenge remains to provide a DAC output signal that tracks absolute temperature voltage variations of an input reference voltage. Aspects of the present disclosure contemplate using resistors, transistor switches, and current mirrors to provide better PVT accuracy and solutions based on current references.

In this regard, it should be noted that DACs usually have two input rails: an upper rail and a lower rail. In static operation, the upper rail is normally supplied to Vdd and the lower rail to ground or Vss. For reference or temperature tracking, the upper rail can be connected to a reference voltage instead of Vdd. Aspects of the present disclosure have the reference voltage supplied to the upper rail of the DAC level shifted (down) to the lower rail of the DAC. This allows the lower rail to track the upper rail instead of ground, and thus, the absolute difference between the upper rail and the lower rail will change identically with temperature instead of one rail being constant at ground and the other rail varying with temperature. Thus, the DAC is implemented with a resistor divider network (which provides good PVT accuracy).

As a further effort to address temperature variation, aspects of the present disclosure contemplate making matching temperature profiles for sub-circuits. Thus, aspects of the present disclosure contemplate such a temperature profile, where the profiler uses a first current reference (e.g., betamultiplier) with a first temperature coefficient and a second current reference with a second temperature coefficient. A first transistor is coupled (at its gate) to the first current reference, and a second transistor is coupled (at its gate) to the second current reference. The second transistor is coupled to the first transistor (drain to drain), so the current of the second transistor subtracts from the current of the first transistor (e.g., the first transistor is a PFET, and the second transistor is an NFET), and the first and second temperature profiles of the current thereby subtracts, resulting in a third temperature profile of the difference output current. The temperature coefficient can be profiled by changing the W/L ratios (e.g., programmable) of the first and second transistors (see discussion of transistor 268A above). Additional temperature profiles can be created by adding transistors and setting W/L ratios. As such, a first current source temperature with temperature profile T1 may source (or sink) the bias current to op-amp 402, a second Ibias with a second temperature profile T2 may source (or sink) to Ibias of transistors 450 and 440, a third bias current with temperature profile T3 may source (or sink) to Iref of FIG. 4, a fourth current source with temperature profile T4 may be supplied from current source 504, and a fifth current may source (or sink) to the current stealing device of 1100. By selecting the desired temperature profiles, the composite temperature profile may be molded into a desired temperature profile (e.g., constant).

Note while subtracting is contemplated, the transistors may be of the same type (i.e., both PFET or both NFET), and the currents could be summed.

Armed with the power detector described above, it is also possible to have a self-calibration circuit that may assist designers in verifying operation and performing tests on the transmission chain. Such ability may reduce the time to test and/or free testing equipment for other uses. The calibrations may extend across PVT variations.

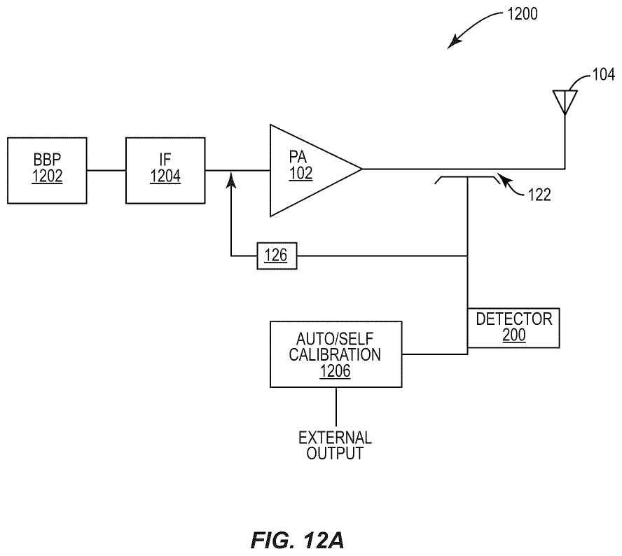

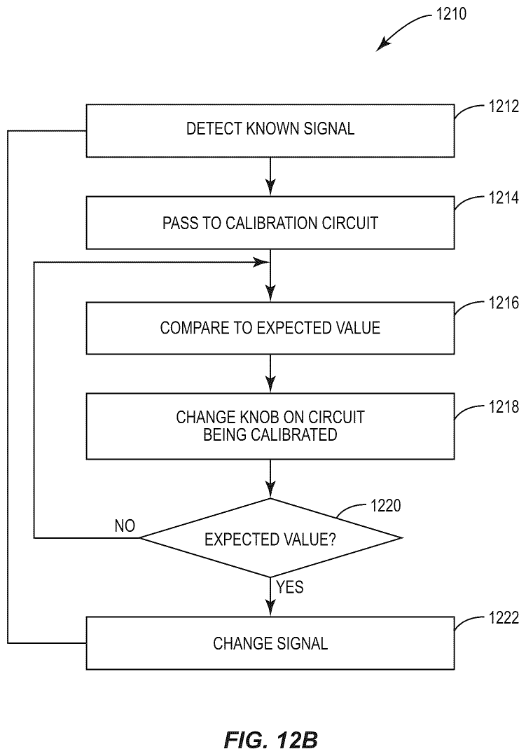

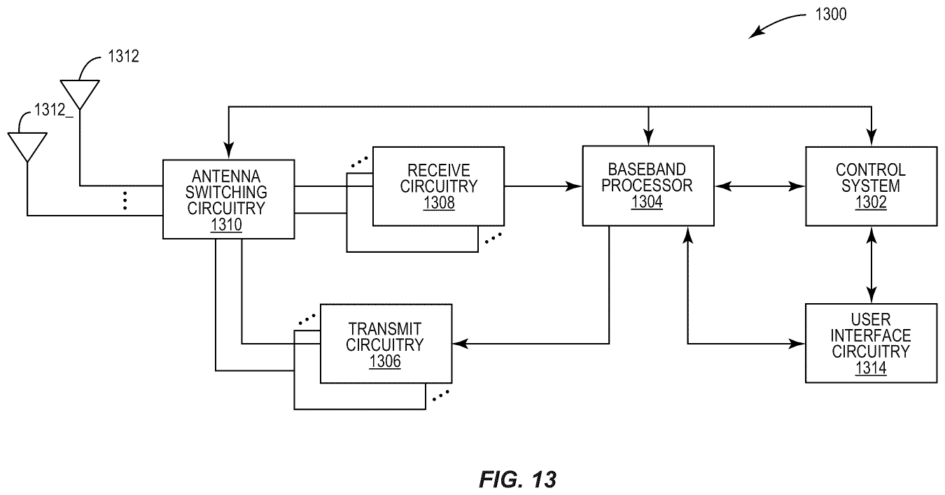

Additional details are provided with reference to FIG. 12A. Specifically, a wireless communication device 1200 may include a baseband processor (BBP) 1202, an intermediate frequency (IF) processor 1204 that upconverts signals and may provide some additional signal conditioning, the power amplifier 102, a coupler 122, a power detector 200 according to the present disclosure, a throttle circuit 126 and an antenna 104. An autocalibration or self-calibration circuit 1206 may receive signals from the detector 200 and use them to perform diagnostics or calibration activities. Further the self-calibration circuit 1206 may include an external output 1208. More details are provided with reference to flowcharts in FIG. 12B.

In this regard, FIG. 12B illustrates a process 1210, where the detector 200 may detect a known signal (block 1212). This known signal may be generated in the BBP 1202 or received from an external source through the antenna 104. The known signal is subjected to known signal conditioning (i.e., a known bias applied to the power amplifier, a known clock applied to mix to an intermediate frequency, or the like).

The detected signal is passed to the autocalibration circuit 1206 (block 1214). Note that in some cases, the detector 200 may be repositioned (or duplicated) to measure signals at different points along a receive or transmission path. The autocalibration circuit 1206 compares the detected signal to an expected value (block 1216). Based on the comparison, a “knob” on the circuit being calibrated may be changed (block 1218) to see if that adjustment makes the detected signal closer or further from the expected value. Knobs in this context may be currents or voltages applied to the transmission or receive path through bias circuits, supply voltages, variable resistances, variable impedances, variable capacitances, or the like.

The calibration circuit determines if the detected value is the expected value (block 1220). If the answer is no, the process iterates through multiple changes potentially. If the answer is yes, then known signal is changed (block 1222), and the process iterates. The signal change may be a continuous (i.e., analog) change or a step change. Desired results and knob settings may be stored in memory for use in operation. Where multiple knobs affect the detected signal, these sorts of detections may be stored in a matrix, and “best fit” options selected.

The power detectors according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

FIG. 13 is a schematic diagram of an exemplary communication device 1300 wherein the power detector 200 (and its variations) can be provided. Herein, the communication device 1300 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1300 will generally include a control system 1302, a baseband processor 1304, transmit circuitry 1306, receive circuitry 1308, antenna switching circuitry 1310, multiple antennas 1312, and user interface circuitry 1314. In a non-limiting example, the control system 1302 can be a field-programmable gate array (FPGA) or an application-specific integrated circuit (ASIC), as an example. In this regard, the control system 1302 can include at least a microprocessor(s), an embedded memory circuit(s), and a communication bus interface(s). The receive circuitry 1308 receives radio frequency signals via the antennas 1312 and through the antenna switching circuitry 1310 from one or more base stations. A low noise amplifier and a filter of the receive circuitry 1308 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1304 processes the digitized received signal to extract the information or data bits conveyed in the received signal. This processing typically comprises demodulation, decoding, and error correction operations. The baseband processor 1304 is generally implemented in one or more digital signal processors (DSPs) and ASICs.

For transmission, the baseband processor 1304 receives digitized data, which may represent voice, data, or control information, from the control system 1302, which it encodes for transmission. The encoded data is output to the transmit circuitry 1306, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1312 through the antenna switching circuitry 1310. The power detector 200 of the present disclosure may be associated with the antennas 1312. The multiple antennas 1312 and the replicated transmit and receive circuitries 1306, 1308 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power detector comprising:
a forward power detector circuit configured to receive a forward signal from a coupler associated with a transmission path conductor;
a reverse power detector circuit configured to receive a reverse signal from the coupler associated with the transmission path conductor, wherein the reverse signal is based on a signal reflected from an antenna;
a summing node configured to:
receive a first current from the forward power detector circuit;
receive a second current from the reverse power detector circuit; and
sum the first current and the second current into a combined power-detected signal.

2. The power detector of claim 1, further comprising a boost circuit configured to receive the forward signal and generate a boosted signal when the forward signal is below a threshold.

3. The power detector of claim 1, wherein the reverse power detector circuit does not generate the second current when the reverse signal is below a threshold.

4. The power detector of claim 3, further comprising a transistor in the reverse power detector circuit configured to program the threshold.

5. The power detector of claim 1, wherein the forward power detector circuit comprises a plurality of stacked diodes configured to rectify the forward signal to a direct current (DC) signal.

6. The power detector of claim 1, wherein the reverse power detector circuit comprises a plurality of stacked diodes configured to rectify the reverse signal to a direct current (DC) signal.

7. The power detector of claim 5, further comprising a bias circuit connected to the forward power detector circuit and configured to bias a transistor serially positioned with the plurality of stacked diodes;
the bias circuit further configured to bias a second transistor in the reverse power detector circuit.

8. The power detector of claim 7, wherein the bias circuit comprises a second plurality of stacked diodes, a current source, and a programmable resistor.

9. The power detector of claim 8, wherein the programmable resistor comprises a digital to analog converter (DAC) connected to a plurality of transistors such that different resistors are activated depending on which of the plurality of transistors are activated by the DAC.

10. The power detector of claim 8, wherein the current source is temperature compensated.

11. The power detector of claim 1, wherein the reverse power detector circuit further comprises:
an input node;
a first current mirror coupled to the input node through a diode; and
a second current mirror coupled to the first current mirror and the summing node.

12. The power detector of claim 11, wherein the first current mirror is configured to remain off until the reverse signal rises above a threshold.

13. The power detector of claim 11, wherein the second current mirror comprises a binary array of transistors configured to allow selection of a gain provided by the second current mirror.

14. A mobile communication device comprising:
a transmission chain comprising:
a baseband processor (BBP);
a power amplifier coupled to the BBP; and
a power detector coupled to an output of the power amplifier, the power detector comprising:
a forward power detector circuit configured to receive a forward signal from a coupler associated with a transmission path conductor;
a reverse power detector circuit configured to receive a reverse signal from the coupler associated with the transmission path conductor, wherein the reverse signal is based on a signal reflected from an antenna;
a summing node configured to:
receive a first current from the forward power detector circuit;
receive a second current from the reverse power detector circuit; and
sum the first current and the second current into a combined power-detected signal.

15. The mobile communication device of claim 14, wherein the power detector further comprises a boost circuit configured to receive the forward signal and generate a boosted signal when the forward signal is below a threshold.

16. The mobile communication device of claim 14, wherein the reverse power detector circuit does not generate the second current when the reverse signal is below a threshold.

17. The mobile communication device of claim 16, further comprising a transistor in the reverse power detector circuit configured to program the threshold.

18. The mobile communication device of claim 14, further comprising an autocalibration circuit coupled to the power detector.

19. A method of calibrating a mobile communication device, comprising:
detecting a forward signal downstream of a power amplifier;
detecting a reverse signal reflected from an antenna downstream of the power amplifier; and
providing the detected signal to an autocalibration circuit.

20. The method of claim 19, further comprising: adjusting a knob in a transmission circuit based on a signal from the autocalibration circuit.
